(19) United States
(12) Patent Application Publication
(10) Pub. No.: US 2026/0150648 A1
(43) Pub. Date: May 28, 2026

(54) SEMICONDUCTOR COMPONENT WITH FINGER-STRUCTURED METAL ROUTING LAYOUT

(71) Applicant: PANSTAR SEMICONDUCTOR CO., LTD., Hsinchu (TW)

(72) Inventor: I-Hua LIN, Hsinchu (TW)

(21) Appl. No.: 19/335,354

(22) Filed: Sep. 22, 2025

(30) Foreign Application Priority Data
Nov. 25, 2024 (TW) 113145365

(51) Int. Cl. H01L 23/528; H01L 23/522

(52) U.S. Cl. CPC H10W 20/427; H10W 20/43; H10W 20/435; H10W 20/495

(57) ABSTRACT

A semiconductor component with a finger-structured metal routing layout is disclosed. The semiconductor component includes a semiconductor substrate, a first pad and a second pad. The semiconductor substrate includes a first region and a second region with different polarities. The first pad is disposed on the first region. The first pad includes multi-layer of metal and has a multi-layer height. The second pad is disposed on the second region. The second pad includes a single-layer of metal and has a single-layer height. The multi-layer height is larger than the single-layer height, so that a side area of multi-layer metal of the first pad relative to the second pad is larger than a side area of single-layer metal of the second pad relative to the first pad.

### CROSS-REFERENCE TO RELATED APPLICATION

This application claims the priority benefit of Taiwan application serial no. 113145365 filed on Nov. 25, 2024. The contents of the above-mentioned patent application are incorporated by reference herein in their entireties and made a part of this specification.

### TECHNICAL FIELD

The invention relates to a semiconductor component, and more particularly to a semiconductor component with a finger-structured metal routing layout.

### BACKGROUND

Please refer to FIG. 1 and FIG. 2, which are a top view and a side view of a conventional semiconductor component with a finger-structured metal routing layout respectively. Since the finger-structured metal routing layout is used for the conventional semiconductor component (such as a diode component, but not limited to this) 1, when the current flows from a first pad (such as an input/output pad) IP1 to a second pad (such as a ground pad) GP1, there will be a phenomenon of uneven current conduction.

In order to improve this phenomenon of uneven current conduction, a conventional solution is to dispose multiple metal layers PM1˜PM2 and NM1˜NM2 on the first pad IP1 and the second pad GP1 respectively, as shown in FIG. 2. However, since a parasitic capacitance C1 formed between the first pad IP1 and the second pad GP1 is proportional to a metal side area relative to each other of the first pad IP1 and the second pad GP1 and inversely proportional to a distance between the first pad IP1 and the second pad GP1, although the distance between the first pad IP1 and the second pad GP1 is fixed, the metal side area relative to each other of the first pad IP1 and the second pad GP1 increases, the parasitic capacitance C1 formed between the first pad IP1 and the second pad GP1 also increases, which seriously affects the physical characteristics of the semiconductor component and needs to be further resolved.

### SUMMARY

In view of this, a semiconductor component with a finger-structured metal routing layout is proposed in the invention to effectively solve the above-mentioned problems in the prior art.

An embodiment of the invention is a semiconductor component with a finger-structured metal routing layout. In this embodiment, the semiconductor component includes a semiconductor substrate, a first pad and a second pad. The semiconductor substrate includes a first region and a second region with different polarities. The first pad is disposed on the first region. The first pad includes a multi-layer metal and has a multi-layer height. The second pad is disposed on the second region. The second pad includes a single-layer metal and has a single-layer height. The multi-layer height is larger than the single-layer height, so that a side area of the multi-layer metal of the first pad relative to the second pad is larger than a side area of the single-layer metal of the second pad relative to the first pad.

In an embodiment, the first pad is an input/output pad and the second pad is a ground pad.

In an embodiment, the semiconductor substrate is N-type, the first region is P-type and the second region is N-type, the first region is smaller than the second region and the multi-layer metal of the first pad is smaller than the single-layer metal of the second pad.

In an embodiment, if a distance between the first pad and the second pad is fixed, a parasitic capacitance between the first pad and the second pad is proportional to the side area of the single-layer metal.

Another embodiment of the invention is a semiconductor component with a finger-structured metal routing layout. In this embodiment, the semiconductor component includes a semiconductor substrate, a first pad and a second pad. The semiconductor substrate includes a first region and a second region with different polarities. The first pad is disposed on the first region. The first pad includes a single-layer metal and has a single-layer height. The second pad is disposed on the second region. The second pad includes a multi-layer metal and has a multi-layer height. The single-layer height is smaller than the multi-layer height, so that a side area of the single-layer metal of the first pad relative to the second pad is smaller than a side area of the multi-layer metal of the second pad relative to the first pad.

In an embodiment, the first pad is an input/output pad and the second pad is a ground pad.

In an embodiment, the semiconductor substrate is N-type, the first region is P-type and the second region is N-type, the first region and the second region have the same size and the single-layer metal of the first pad and the multi-layer metal of the second pad have the same size.

In an embodiment, if a distance between the first pad and the second pad is fixed, a parasitic capacitance between the first pad and the second pad is proportional to the side area of the single-layer metal.

Another embodiment of the invention is a semiconductor component with a finger-structured metal routing layout. In this embodiment, the semiconductor component includes a semiconductor substrate, a first pad and a second pad. The semiconductor substrate includes a first region and a second region with different polarities. The first pad is disposed on the first region. The first pad includes a single-layer metal and has a single-layer height. The second pad is disposed on the second region. The second pad includes the single-layer metal and has the single-layer height. The first pad and the second pad both have the single-layer height, so that a side area of the single-layer metal of the first pad relative to the second pad is equal to the side area of the single-layer metal of the second pad relative to the first pad.

In an embodiment, the first pad is an input/output pad and the second pad is a ground pad.

In an embodiment, the semiconductor substrate is N-type, the first region is P-type and the second region is N-type, the first region is smaller than the second region and the single-layer metal of the first pad is smaller than the single-layer metal of the second pad.

In an embodiment, if a distance between the first pad and the second pad is fixed, a parasitic capacitance between the first pad and the second pad is proportional to the side area of the single-layer metal.

Compared with the prior art, the semiconductor component with a finger-structured metal routing layout proposed by the invention can not only reduce the resistance of the metal connection to effectively improve the phenomenon of uneven conduction current, but also reduce the metal side area corresponding to the input/output pad and the ground pad to effectively avoid the increase of the metal parasitic capacitance and improve the physical properties of the semiconductor component.

### BRIEF DESCRIPTION OF THE DRAWINGS

The drawings presented in this disclosure are intended to help describe various embodiments of the invention. However, in order to simplify the drawings and/or highlight the contents to be presented in the drawings, well-known structures and/or components in the drawings may be depicted in a simplified schematic manner or presented in an omitted manner. On the other hand, the number of components in the drawings may be singular or plural. The drawings presented in this disclosure are only for the purpose of illustrating the embodiments and are not intended to limit the same.

FIG. 1 and FIG. 2 are a top view and a side view of a conventional semiconductor component with a finger-structured metal routing layout respectively.

FIG. 3 and FIG. 4 are a top view and a side view of a semiconductor component with a finger-structured metal routing layout in an embodiment of the invention respectively.

FIG. 5 is a side view of a semiconductor component with a finger-structured metal routing layout in another embodiment of the invention respectively.

FIG. 6 is a side view of a semiconductor component with a finger-structured metal routing layout in another embodiment of the invention respectively.

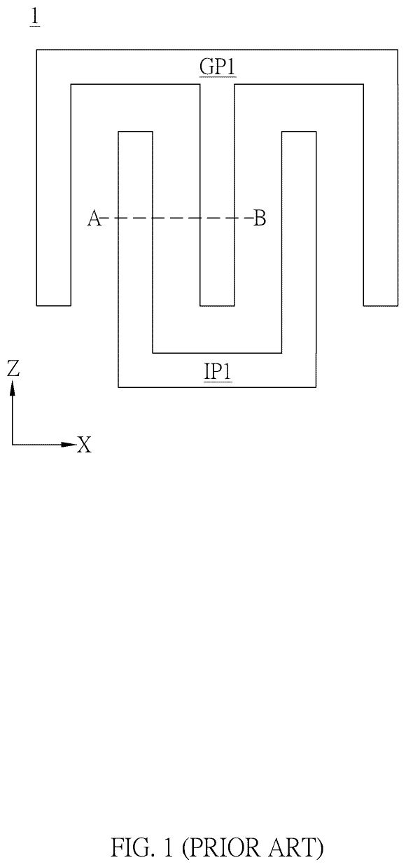

### DETAILED DESCRIPTION

Any reference to components herein using names such as “first,” “second,” etc. does not generally limit the number or order of these components. Rather, these names are used herein as a convenient way of distinguishing between two or more components or instances of a component. Therefore, it should be understood that the names “first”, “second”, etc. in the claims do not necessarily correspond to the same names in the written description. Additionally, it should be understood that a reference to first and second components does not mean that only two components may be employed or that the first component must precede the second component. The words “include,” “including,” “have,” “contain,” etc. used in this article are open-ended terms, meaning including but not limited to.

In this disclosure, the words “exemplary” and “for example” are used to mean “serving as an example, instance, or illustration.” Any implementation or aspect described herein as “exemplary,” “for example,” is not necessarily to be construed as preferred or advantageous over other aspects of the invention.

An embodiment of the invention is a semiconductor component with a finger-structured metal routing layout. In practical applications, the semiconductor component can be, for example, a diode component, but not limited to this. In this embodiment, the semiconductor component at least includes a semiconductor substrate, a first pad and a second pad. The semiconductor substrate includes a first region and a second region having different polarities (e.g., P-type and N-type). The first pad is disposed on the first region. The first pad includes a multi-layer metal and has a multi-layer height. The second pad is disposed on the second region. The second pad includes a single-layer metal and has a single-layer height. The multi-layer height is larger than the single-layer height, so that a side area of the multi-layer metal of the first pad relative to the second pad is larger than a side area of the single-layer metal of the second pad relative to the first pad.

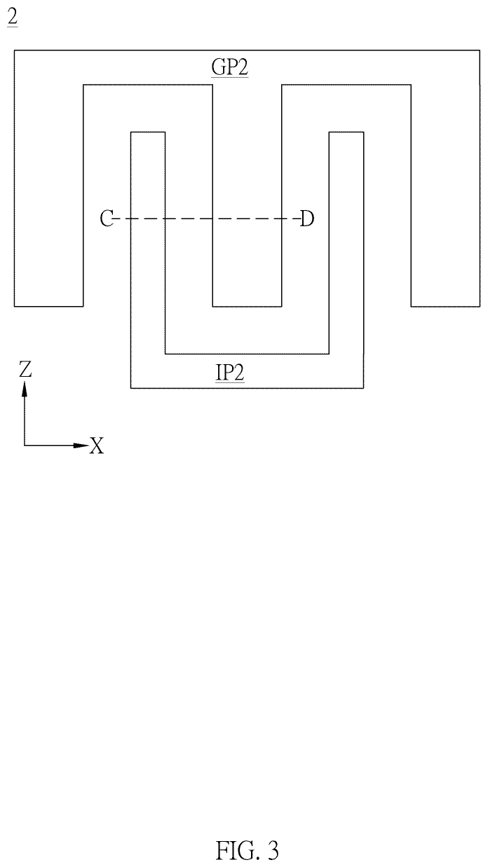

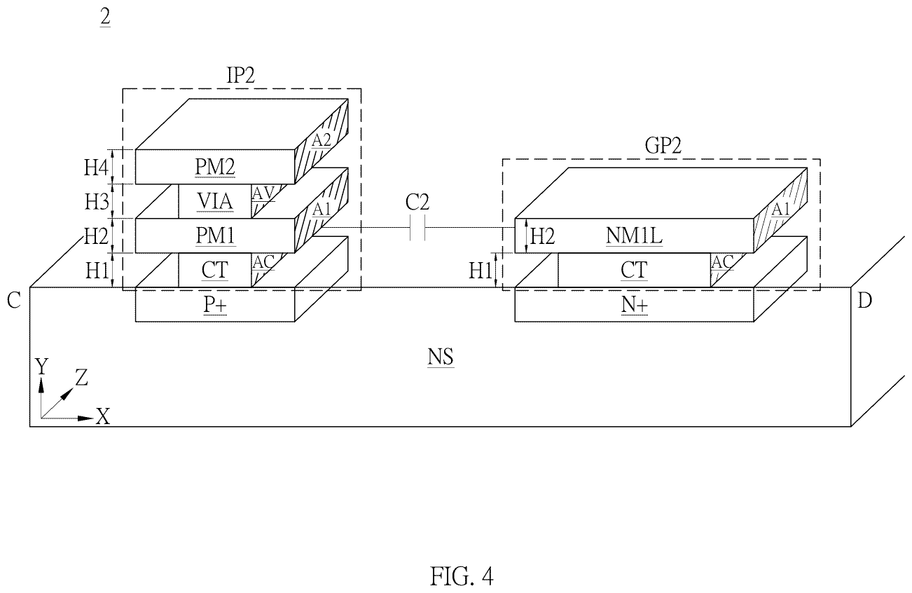

Specifically, please refer to FIG. 3 and FIG. 4. FIG. 3 is a top view of the semiconductor component 2 with a finger-structured metal routing layout in this embodiment, and FIG. 4 is a side view of the semiconductor component 2 from a point C to a point D in FIG. 3. As shown in FIG. 3, the semiconductor component 2 includes a first pad IP2 and a second pad GP2, and the first pad IP2 and the second pad GP2 form a metal routing layout with a finger structure.

As shown in FIG. 4, the semiconductor component 2 includes a semiconductor substrate NS, a first pad IP2 and a second pad GP2. The semiconductor substrate NS includes a first region P+ and a second region N+ having different polarities, and a width of the first region P+ is smaller than a width of the second region N+. In this embodiment, the semiconductor substrate NS can be an N-type substrate, and the first region P+ and the second region N+ can be a P-type doped region and an N-type doped region formed on the surface of the semiconductor substrate NS respectively, and the width of the P-type doped region can be smaller than the width of the N-type doped region, but not limited to this.

The first pad IP2 is disposed on the first region P+ and the second pad GP2 is disposed on the second region N+. In this embodiment, the first pad IP2 can be an input/output (I/O) pad and the second pad GP2 can be a ground pad, and the width of the first pad IP2 can be smaller than that of the second pad GP2, but not limited to this.

The first pad IP2 includes a multi-layer metal and has a multi-layer height, and the second pad GP2 includes a single-layer metal and has a single-layer height. The multi-layer height is larger than the single-layer height. In this embodiment, the first pad IP2 disposed on the first region P+ includes a contact layer CT, a first metal layer PM1, a via layer VIA and a second metal layer PM2 in sequence from bottom to top. The contact layer CT is disposed on the first region P+. The first metal layer PM1 is disposed on the contact layer CT. The via layer VIA is disposed on the first metal layer PM1. The second metal layer PM2 is disposed on the via layer VIA. The second pad GP2 disposed on the second region N+ includes a contact layer CT and a first metal layer NM1L in sequence from bottom to top. The contact layer CT is disposed on the second region N+. The first metal layer NM1L is disposed on the contact layer CT. A width of the first metal layer NM1L of the second pad GP2 is larger than a width of the first metal layer PM1 and the second metal layer PM2 of the first pad IP2. The contact layer CT and the via layer VIA are made of a conductive material such as metal.

It should be noted that the multi-layer height of the first pad IP2 includes a sum of a height H1 of the contact layer CT, a height H2 of the first metal layer PM1, a height H3 of the via layer VIA and a height H4 of the second metal layer PM2, while the single-layer height of the second pad GP2 only includes a sum of the height H1 of the contact layer CT and the height H2 of the first metal layer NM1L. Therefore, the multi-layer height of the first pad IP2 is significantly larger than the single-layer height of the second pad GP2.

Similarly, a side area of the multi-layer metal of the first pad IP2 relative to the second pad GP2 includes a sum of a side area AC of the contact layer CT, a side area A1 of the first metal layer PM1, a side area AV of the via layer VIA and a side area A2 of the second metal layer PM2, while a side area of the single-layer metal of the second pad GP2 relative to the first pad IP2 only includes a sum of the side area AC of the contact layer CT and the side area A1 of the first metal layer NM1L. Therefore, the side area of the multi-layer metal of the first pad IP2 relative to the second pad GP2 is significantly larger than the side area of the single-layer metal of the second pad GP2 relative to the first pad IP2.

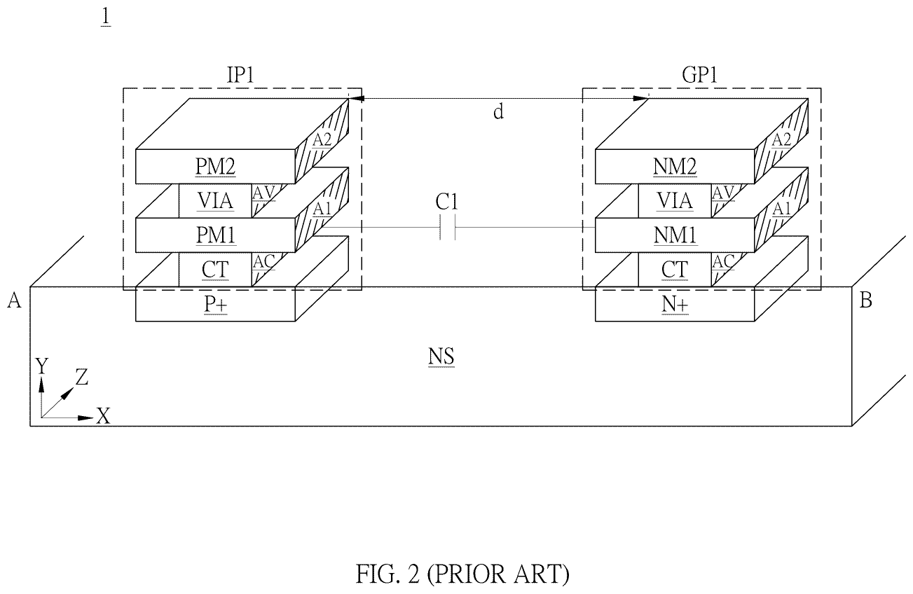

By comparing FIG. 4 of the present embodiment with FIG. 2 of the prior art, it can be seen that the metal side area of the first pad IP1 relative to the second pad GP1 in FIG. 2 of the prior art is equal to a sum of (AC+A1+AV+A2), while the metal side area of the first pad IP2 relative to the second pad GP2 in FIG. 4 of the present embodiment is only a sum of (AC+A1); that is, the metal side area of the first pad IP2 relative to the second pad GP2 in FIG. 4 of the present embodiment is significantly smaller than the metal side area of the first pad IP1 relative to the second pad GP1 in FIG. 2 of the prior art. Since the magnitude of the parasitic capacitance formed between the two pads is proportional to the metal side area facing each other between the two pads; therefore, when the distance between the two pads is fixed, the parasitic capacitance C2 formed between the first pad IP2 and the second pad GP2 in FIG. 4 of the present embodiment will be significantly smaller than the parasitic capacitance C1 formed between the first pad IP1 and the second pad GP1 in FIG. 2 of the prior art. That is, the semiconductor component 2 proposed by the invention can indeed effectively reduce the parasitic capacitance formed between its input/output pad and the ground pad, thereby effectively solving the problem in the prior art that the physical properties of the semiconductor component are seriously affected by the increase of the parasitic capacitance between the input/output pad and the ground pad.

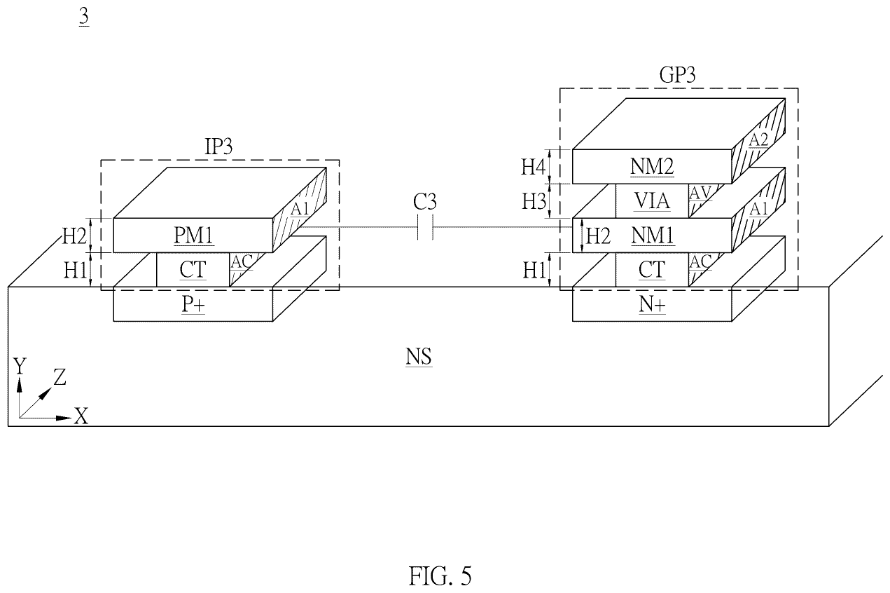

Please refer to FIG. 5, which is a side view of a semiconductor component 3 with a finger-structured metal routing layout in another embodiment of the invention. As shown in FIG. 5, the semiconductor component 3 includes a semiconductor substrate NS, a first pad IP3 and a second pad GP3. The semiconductor substrate NS includes a first region P+ and a second region N+ having different polarities, and a width of the first region P+ is equal to a width of the second region N+. In this embodiment, the semiconductor substrate NS can be an N-type substrate and the first region P+ and the second region N+ can be a P-type doped region and an N-type doped region formed on the surface of the semiconductor substrate NS respectively, and the width of the P-type doped region is equal to the width of the N-type doped region, but not limited to this.

The first pad IP3 is disposed on the first region P+ and the second pad GP3 is disposed on the second region N+. In this embodiment, the first pad IP3 may be an input/output pad and the second pad GP3 may be a ground pad, and the width of the first pad IP3 is equal to the width of the second pad GP3, but not limited to this.

The first pad IP3 includes a single-layer metal and has a single-layer height, and the second pad GP3 includes a multi-layer metal and has a multi-layer height. In this embodiment, the first pad IP3 disposed on the first region P+ only includes the contact layer CT and the first metal layer PM1 from bottom to top. The contact layer CT is disposed on the first region P+. The first metal layer PM1 is disposed on the contact layer CT. The second pad GP3 disposed on the second region N+ includes a contact layer CT and a first metal layer NM1, a via layer VIA and a second metal layer NM2 in sequence from bottom to top. The contact layer CT is disposed on the second region N+. The metal layer NM1 is disposed on the contact layer CT. The via layer VIA is disposed on the first metal layer PM1. The second metal layer PM2 is disposed on the via layer VIA. The widths of the first metal layer NM1 and the second metal layer NM2 of the second pad GP3 are equal to the width of the first metal layer PM1 of the first pad IP3. The contact layer CT and the via layer VIA are made of a conductive material such as metal.

It should be noted that, as shown in FIG. 5, a multi-layer height of the second pad GP3 includes a sum of a height H1 of the contact layer CT, a height H2 of the first metal layer NM1, a height H3 of the via layer VIA and a height H4 of the second metal layer NM2, while a single-layer height of the first pad IP3 only includes a sum of the height H1 of the contact layer CT and the height H2 of the metal layer PM1. Therefore, the multi-layer height of the second pad GP3 is significantly larger than the single-layer height of the first pad IP3.

Similarly, the side area of the multi-layer metal of the second pad GP3 relative to the first pad IP3 (equal to a sum of AC+A1+AV+A2) is significantly larger than the side area of the single-layer metal of the first pad IP3 relative to the second pad GP3 (equal to a sum of AC+A1). By comparing FIG. 5 of the present embodiment with FIG. 2 of the prior art, it can be seen that the metal side area of the first pad IP1 relative to the second pad GP1 in FIG. 2 of the prior art is equal to a sum of (AC+A1+AV+A2), while the metal side area of the first pad IP3 relative to the second pad GP3 in FIG. 5 of the present embodiment is only a sum of (AC+A1), that is, the metal side area of the first pad IP3 relative to the second pad GP3 in FIG. 5 of the present embodiment is significantly smaller than the metal side area of the first pad IP1 relative to the second pad GP1 in FIG. 2 of the prior art. Since the magnitude of the parasitic capacitance formed between the two pads is proportional to the metal side area facing each other between the two pads; therefore, when the distance between the two pads is fixed, the parasitic capacitance C3 formed between the first pad IP3 and the second pad GP3 of the semiconductor component 3 in FIG. 5 of the present embodiment will be significantly smaller than the parasitic capacitance C1 formed between the first pad IP1 and the second pad GP1 of the semiconductor component 1 in FIG. 2 of the prior art, thereby effectively solving the problem in the prior art that the physical properties of the semiconductor component are seriously affected by the increase in the parasitic capacitance between the input/output pad and the ground pad.

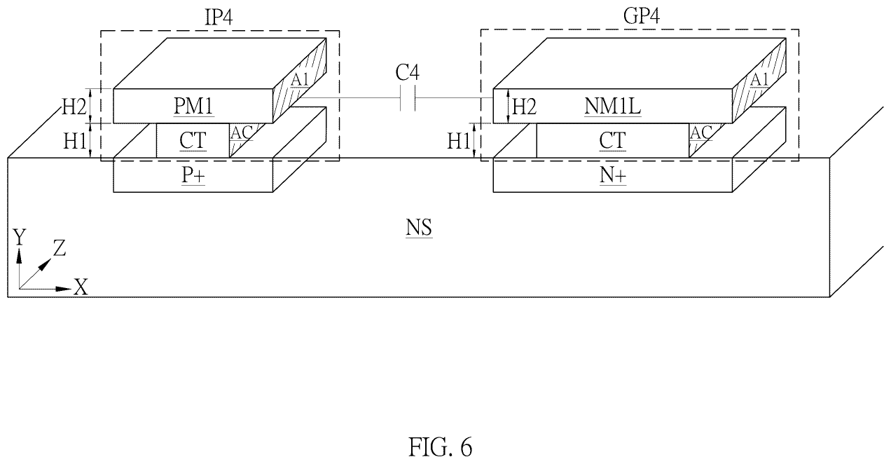

Please refer to FIG. 6, which is a side view of a semiconductor component with a finger-structured metal routing layout in another embodiment of the invention. As shown in FIG. 6, the semiconductor component 4 includes a semiconductor substrate NS, a first pad IP4 and a second pad GP4. The semiconductor substrate NS includes a first region P+ and a second region N+ having different polarities, and a width of the first region P+ is smaller than a width of the second region N+. In this embodiment, the semiconductor substrate NS can be an N-type substrate and the first region P+ and the second region N+ can be a P-type doped region and an N-type doped region respectively formed on the surface of the semiconductor substrate NS, and the width of the P-type doped region can be smaller than the width of the N-type doped region, but not limited to this.

The first pad IP4 is disposed on the first region P+ and the second pad GP4 is disposed on the second region N+. In this embodiment, the first pad IP4 can be an input/output pad and the second pad GP4 can be a ground pad, and the width of the first pad IP4 can be smaller than the width of the second pad GP4, but not limited to this.

The first pad IP4 and the second pad GP4 both include a single-layer metal and have a single-layer height. In this embodiment, the first pad IP4 disposed on the first region P+ includes a contact layer CT and a first metal layer PM1 in sequence from bottom to top. The contact layer CT is disposed on the first region P+. The first metal layer PM1 is disposed on the contact layer CT. The second pad GP4 disposed on the second region N+ includes a contact layer CT and a first metal layer NM1L in sequence from bottom to top. The contact layer CT is disposed on the second region N+. The first metal layer NM1L is disposed on the contact layer CT. The width of the first metal layer NM1L of the second pad GP4 can be larger than the width of the first metal layer PM1 of the first pad IP4. The contact layer CT is composed of a conductive material such as metal.

It should be noted that, as shown in FIG. 6, the single-layer height of the second pad GP4 includes a sum of a height H1 of the contact layer CT and a height H2 of the first metal layer NM1L, and the single-layer height of the first pad IP4 includes a sum of the height H1 of the contact layer CT and the height H2 of the metal layer PM1. Therefore, the single-layer height of the second pad GP4 is equal to the single-layer height of the first pad IP4. Similarly, the side area of the single-layer metal of the second pad GP4 relative to the first pad IP4 is equal to the side area of the single-layer metal of the first pad IP4 relative to the second pad GP4 (both are equal to the sum of AC+A1). According to the description of the aforementioned embodiment, it can be seen that the metal side area of the first pad IP4 and the second pad GP4 relative to each other in FIG. 6 of this embodiment (equal to the sum of AC+A1) is significantly smaller than the metal side area of the first pad IP1 and the second pad GP1 relative to each other in FIG. 2 of the prior art (equal to the sum of AC+A1+AV+A2). Since the magnitude of the parasitic capacitance formed between the two pads is proportional to the metal side area facing each other between the two pads; therefore, when the distance between the two pads is fixed, the parasitic capacitance C4 formed between the first pad IP4 and the second pad GP4 of the semiconductor component 4 in FIG. 6 of the present embodiment will be significantly smaller than the parasitic capacitance C1 formed between the first pad IP1 and the second pad GP1 of the semiconductor component 1 in FIG. 2 of the prior art, thereby effectively solving the problem in the prior art that the physical properties of the semiconductor component are seriously affected by the increase in the parasitic capacitance between the input/output pad and the ground pad.

The contents disclosed above are merely feasible embodiments of the invention, and are not intended to limit the scope of the claims of the invention. Therefore, all equivalent technical changes made based on the specification and the drawings of the invention fall within the scope of the claims of the invention.

What is claimed is:

1. A semiconductor component with a finger-structured metal routing layout, comprising:
a semiconductor substrate comprising a first region and a second region with different polarities;
a first pad, disposed on the first region, comprising a multi-layer metal and having a multi-layer height; and
a second pad, disposed on the second region, comprising a single-layer metal and having a height of single-layer;
wherein the multi-layer height is larger than the height of single-layer, so that a side area of the multi-layer metal of the first pad relative to the second pad is larger than a side area of the single-layer metal of the second pad relative to the first pad.

2. The semiconductor component according to claim 1, wherein the first pad is an input/output pad and the second pad is a ground pad.

3. The semiconductor component according to claim 2, wherein the semiconductor substrate is N-type, the first region is P-type and the second region is N-type, the first region is smaller than the second region and the multi-layer metal of the first pad is smaller than the single-layer metal of the second pad.

4. The semiconductor component according to claim 1, wherein if a distance between the first pad and the second pad is fixed, a parasitic capacitance between the first pad and the second pad is proportional to the side area of the single-layer metal.

5. A semiconductor component with a finger-structured metal routing layout, comprising:
a semiconductor substrate comprising a first region and a second region with different polarities;
a first pad, disposed on the first region, comprising a single-layer metal and having a height of single-layer; and
a second pad, disposed on the second region, comprising a multi-layer metal and having a multi-layer height;
wherein the height of single-layer is smaller than the multi-layer height, so that a side area of the single-layer metal of the first pad relative to the second pad is smaller than a side area of the multi-layer metal of the second pad relative to the first pad.

6. The semiconductor component according to claim 5, wherein the first pad is an input/output pad and the second pad is a ground pad.

7. The semiconductor component according to claim 6, wherein the semiconductor substrate is N-type, the first region is P-type and the second region is N-type, the first region and the second region have the same size and the single-layer metal of the first pad and the multi-layer metal of the second pad have the same size.

8. The semiconductor component according to claim 5, wherein if a distance between the first pad and the second pad is fixed, a parasitic capacitance between the first pad and the second pad is proportional to the side area of the single-layer metal.

9. A semiconductor component with a finger-structured metal routing layout, comprising:
a semiconductor substrate comprising a first region and a second region with different polarities;
a first pad, disposed on the first region, comprising a single-layer metal and having a single-layer height; and
a second pad, disposed on the second region, comprising the single-layer metal and having the single-layer height;
wherein the first pad and the second pad both have the single-layer height, so that a side area of the single-layer metal of the first pad relative to the second pad is equal to the side area of the single-layer metal of the second pad relative to the first pad.

10. The semiconductor component according to claim 9, wherein the first pad is an input/output pad and the second pad is a ground pad.

11. The semiconductor component according to claim 10, wherein the semiconductor substrate is N-type, the first region is P-type and the second region is N-type, the first region is smaller than the second region and the single-layer metal of the first pad is smaller than the single-layer metal of the second pad.

12. The semiconductor component according to claim 9, wherein if a distance between the first pad and the second pad is fixed, a parasitic capacitance between the first pad and the second pad is proportional to the side area of the single-layer metal.
